(19) United States
(12) Patent Application Publication
(10) Pub. No.: US 2024/0290749 A1
(43) Pub. Date: Aug. 29, 2024

(54) Method for manufacturing an electronic device comprising a bonding phase

(71) Applicant: ALEDIA, ÉCHIROLLES (FR)

(72) Inventors: Christophe LINCHENEAU, Moirans (FR); Nohora CAICEDO, Grenoble (FR)

(21) Appl. No.: 18/564,836

(22) PCT Filed: May 24, 2022
(86) PCT No.: PCT/FR2022/050989

§ 371 Date: Nov. 28, 2023

(30) Foreign Application Priority Data
May 31, 2021 (FR) FR21/05711

(51) Int. Cl. H01L 23/00

(52) U.S. Cl. CPC H01L 24/83; H01L 2224/8322

(57) ABSTRACT

The invention relates to a method for manufacturing an electronic device (1) comprising a bonding phase (P1) of said electronic device (1), comprising: —a step (E2) of applying a bonding layer (11) consisting of a photosensitive polymer to a surface of the electronic device (1) and/or to an interface surface (S3) of a manufacturing element (3, 7); —a step (E4) of bringing the manufacturing element (3, 7) into contact with the electronic device (1) so as to adhere the manufacturing element (3, 7) to the electronic device (1) via the bonding layer (11); and a release phase (P4), in which the bonding layer (11) is exposed to a first light radiation having a first wavelength so as to dissociate the manufacturing element (3, 7) from the bonding layer (11).

### TECHNICAL FIELD OF THE INVENTION

The present invention concerns a method for manufacturing an electronic device comprising a bonding phase of said electronic device.

### STATE OF THE ART

In the field of luminous display screens, the luminous elements constituting the screen must be arranged in a matrix fashion in an increasingly precise manner as the resolution of the screens increases. These luminous elements each comprise at least one light-emitting diode and are organized in the form of a multicolor pixel or in the form of a monochrome sub-pixel.

It is known to produce the light-emitting diodes on an initial support in the form of a silicon or sapphire substrate and to report them, by compression or even thermocompression, on a receiving support different from the initial support and intended to constitute, after this transfer by pressure or thermocompression, the luminous display screen. In order to transfer the light-emitting diodes, it is known to use thermosensitive or thermolabile glues which are melted to allow the adhesion or alternatively the release of the diodes to be transferred. However, the use of a thermolabile glue has the disadvantage of requiring a rise in temperature which may damage the chips. Furthermore, the use of glue generally requires a release by mechanical traction, followed by a treatment to remove residue. A dirty surface poses problems with glass surface planarization, for example.

Prior to their transfer, it is generally necessary to separate them in order to individualize them. For this, it is possible to separate them by means of a blade, by a mechanical method. This method is satisfactory in that it makes it possible to separate the diodes. On the other hand, it may induce mechanical stress and sometimes lead to damage to the diodes. It is also possible to operate this separation via a laser. This method has the advantage of allowing the cutting of the chips without generating mechanical stress. However, the laser ablation sometimes generates a deposit of material on the diodes which can affect the final rendering of the luminous display screens.

Thus, it is generally preferable to use a plasma etching cutting method, in particular for the carrying out of very fine cutting, in the range of a few micrometers in width. This method consists in photolithography depositing, a resin on the surface of the diodes. A chemical development makes it possible to remove the resin on the areas intended to be etched by the plasma. This method involves many additional method steps and a high consumption of consumables. As a replacement for resins, it is possible to use metal masks deposited on the diodes and then proceed to plasma etching. The advantage of a metal mask compared to the use of a resin is that it makes it possible to achieve finer cutout dimensions than what is possible to achieve with a resin. The main problem with this method comes from the removal of the metal mask which often generates damage to the surface of the chips. The removal of a metal mask typically requires the use of very strong acidic or basic solvents which generally deteriorate the chips and in particular the light-emitting diodes.

### OBJECT OF THE INVENTION

The purpose of the present invention is to propose a solution which responds to all or part of the aforementioned problems:

This purpose may be achieved through the implementation of a method for manufacturing an electronic device comprising a phase of bonding said electronic device to a manufacturing element, said bonding phase comprising:
a step of providing a primary substrate comprising at least one electronic device;
a step of applying a bonding layer consisting of a photosensitive polymer, during which the bonding layer is applied to a surface of the electronic device so as to secure the bonding layer and the electronic device, and/or to a interface surface of the manufacturing element so as to secure the bonding layer and the manufacturing element;
a step of bringing the manufacturing element into contact with the electronic device so as to adhere the manufacturing element to the electronic device via the bonding layer.

The manufacturing method further comprises a release phase in which the bonding layer is exposed to a first luminous radiation having a first wavelength so as to dissociate the manufacturing element from the electronic device.

The arrangements previously described make it possible to propose a manufacturing method in which the electronic devices are bonded to the manufacturing element via the bonding layer. Additionally, and synergistically, the bonding layer also makes it possible to protect the electronic devices from damage caused by the contact with the manufacturing element or upon removal of the manufacturing element. In addition, the bonding layer advantageously makes it possible to improve the adhesion of the electronic device with the manufacturing element.

By photosensitive polymer is meant a polymer capable of undergoing a photoinduced chemical reaction for its polymerization or its depolymerization. For example, it may be a polymer/photo-initiator pair, such as a positive photoresist, or a polymer precursor and a given photo-initiator, such as a negative photoresist. The photosensitive properties of the polymer also make it possible to simply remove the manufacturing element during the release phase without causing damage to the surface of the electronic device.

Advantageously, the use of a photosensitive polymer makes it possible to implement the steps of the manufacturing method without requiring heating of the bonding layer or of the electronic device. This arrangement is particularly advantageous in that it makes it possible to avoid the problems inherent to heating encountered when using thermolabile glues. Indeed, a rise in temperature risks damaging the electronic device, particularly when it comprises an electronic chip, a quantum-dot, or an electronic control module.

In general, the dissociation of the manufacturing element from the bonding layer is carried out by liquefaction of the photosensitive polymer constituting the bonding layer when it is subjected to the first luminous radiation.

The manufacturing method may also have one or more of the following characteristics, taken alone or in combination.

According to one embodiment, the manufacturing element consists of a manufacturing substrate on which a layer having the interface surface is deposited.

According to one embodiment, the step of bringing the manufacturing element into contact with the electronic device is implemented so as to adhere all or part of the interface surface of the manufacturing element with all or part of the surface to be protected of the electronic device via the bonding layer. It is therefore well understood that, during the step of bringing the manufacturing element into contact with the electronic device, at least part of the interface surface is in direct contact with at least part of a first face of the bonding layer, and that at least part of the surface to be protected is in direct contact with at least part of a second face of the bonding layer opposite to the first face. In this way, the bonding layer is made up of a single element, and serves both to protect the electronic device and to allow its adhesion with the manufacturing element.

According to one embodiment, the bonding phase comprises a step of treating the bonding layer so as to increase the adherence of said bonding layer.

In this way, the bonding layer makes it possible to glue the electronic device with the manufacturing element, and the release phase makes it possible to unglue said manufacturing element from the electronic device.

In other words, the bonding and release phases allow reversible gluing and ungluing of the electronic device and of the manufacturing element.

According to one embodiment, the treatment step comprises exposing the bonding layer to a second luminous radiation having a second wavelength, different from the first wavelength.

According to one embodiment, the second luminous radiation may be configured to increase the surface adhesion of the bonding layer.

In other words, the photosensitive polymer may be chosen so as to have an increase in its adhesive power when it is subjected to a luminous radiation having the second wavelength. For example, the photosensitive polymer may be a positive photoresist such as resins from the family of polysiloxanes, polyformaldehydes, polyhydroxystyrenes, novolacs, polymers from the family of polythiophenes and polyphenylenes, poly(vinyl butyral), polyimide or equivalent. Generally, the photosensitive polymer may comprise a polymer having a polymerization mechanism beginning with a photoinduced initiation.

According to one embodiment, the photosensitive polymer may comprise a photoinitiator configured to polymerize the photosensitive polymer or to depolymerize it.

According to one embodiment, the first luminous radiation and/or the second luminous radiation are emitted by coherent lasers.

In this way, it is possible to select an irradiation area in which the first luminous radiation and/or the second luminous radiation are emitted. Said irradiation area may correspond to a surface covered by a photosensitive polymer, for example the bonding layer.

Advantageously, the power of the coherent luminous radiation may thus be chosen low enough not to damage the electronic device and high enough to make it possible to modify the adhesion of the photosensitive polymer.

According to one embodiment, the manufacturing element comprises a protective mask, the manufacturing method comprising an etching phase implemented after the bonding phase, in which an inter-device element adjacent to the electronic device undergoes an etching, the protective mask being configured to protect the electronic device from said etching.

According to one embodiment, the etching phase is carried out by a plasma etching.

According to one embodiment, the manufacturing method comprises a phase of manufacturing the protective mask, said phase of manufacturing the protective mask comprising the following steps:
a step of depositing a metal layer which is intended to constitute the protective mask;
a step of depositing a photoresist layer on said metal layer;
a step of irradiating the photoresist layer with a luminous radiation through a lithography mask, said lithography mask defining primary areas intended to be irradiated by the luminous radiation, and secondary areas intended to be protected by the lithography mask against the irradiation of said luminous radiation;
a step of developing the photoresist layer in which the photoresist is removed at the primary areas or at the secondary areas, so that the metal layer is no longer covered with photoresist at said areas where the resist layer has been removed, and so that the metal layer is covered with the photoresist layer on the other areas;
an etching step in which an etching of the metal layer is carried out at the areas not covered by the photoresist layer, and in which an etching of the photoresist layer is carried out on the other areas.

According to one embodiment, the etching phase is carried out between the binding phase and the release phase.

According to one embodiment, the protective mask is an aluminum mask, or a chrome mask or an aluminum nitride mask.

According to one embodiment, the protective mask consists of a non-metallic material such as SiO₂, or alternatively by a semi-conducting layer.

According to one embodiment, the gas used for the plasma etching is an octafluorocyclobutane/dioxygen (C₄F₈/O₂) mixture, or carbon tetrafluoride (CF₄), or sulfur hexafluoride (SF₆).

According to one embodiment, the manufacturing method comprises a cleaning phase implemented after the release phase, said cleaning phase comprising a step of removing the photosensitive polymer by jet of plasma, solvent or air.

According to one embodiment, the electronic device comprises an optoelectronic device.

According to one embodiment, the first luminous radiation is an ultraviolet radiation. Alternatively, the first luminous radiation may be an infrared or visible radiation.

For example, the first wavelength may be comprised between 190 nm and 400 nm and more particularly between 254 nm and 400 nm.

In this case, and synergistically, when the electronic device is an optoelectronic device, the photosensitive polymer may absorb a large part of the first luminous radiation, and in this way absorbs the radiation that may be harmful for the optoelectronic device.

According to one embodiment, the manufacturing method comprises a phase of transferring said at least one electronic device from the primary substrate to a secondary substrate implemented after the bonding phase. The transfer phase comprises:
a coupling step during which a transfer support is secured to each electronic device to be transferred;
a step of unhooking said at least one electronic device from the primary substrate by mechanical traction or dry etching;
a step of placing said at least one electronic device on a surface for receiving a secondary substrate.

According to a first embodiment, the manufacturing element consists of the transfer support. The securing of the transfer support to each electronic device is carried out via the bonding layer.

According to this embodiment, the coupling step may be carried out by molding a molding material on each electronic device so as to form the transfer support by hardening the molding material. It is therefore clearly understood that the bonding layer may be disposed between the molding support and the electronic device. Advantageously, the transfer support may have gripping means configured to facilitate the movement of said transfer support.

According to a second embodiment distinct from the first embodiment, the transfer support is configured to cooperate with the manufacturing element, the step of coupling the transfer support to each electronic device to be transferred being implemented via the securing of the transfer support with the manufacturing element. In other words, the transfer support is secured indirectly to each electronic device to be transferred via the manufacturing element.

According to this embodiment, the transfer support may comprise a transfer handle configured to cooperate with the manufacturing element, for example by gluing.

Alternatively, the transfer support may be carried out by molding a molding material on the manufacturing element, so as to form the transfer support by hardening the molding material.

According to one embodiment, the transfer phase further comprises a step of moving the transfer support during which the transfer support is moved so as to implement the unhooking step and/or the positioning step.

According to one embodiment, the transfer phase is implemented before the release phase.

The arrangements previously described make it possible to propose a transfer support capable of simply transferring the optoelectronic device from the primary substrate to the secondary substrate. The bonding layer advantageously makes it possible to protect the electronic device during said transfer from the primary substrate to the secondary substrate. In particular, when the electronic device is an optoelectronic device, the transfer support makes it possible to simply transfer the optoelectronic device from the primary substrate to a substrate for a luminous display screen.

According to one embodiment, the transfer support is made of a stretchable or shrinkable material.

According to one embodiment, the transfer phase comprises a step of stressing the transfer support in which the transfer support is stretched or compressed.

In this way, it is possible to stretch or compress the transfer support to vary a distance between two electronic devices, for example according to a predetermined spacing. Thus it is possible to unhook two electronic devices on the primary substrate according to a first spacing, and to place them on the secondary substrate according to a second spacing different from the first spacing.

For example, the predetermined spacing may be defined as the spacing separating two electronic devices on the secondary substrate. For example, the predetermined spacing may be comprised between 50 μm and 1 mm, and more particularly substantially equal to 100 μm. In this way, the transfer support makes it possible to selectively transfer the electronic devices to be deposited on the secondary substrate.

According to one embodiment, the transfer phase comprises a step of applying an adhesion layer to the transfer support or to a surface of the manufacturing element opposite to its surface intended to come into contact with the bonding layer.

According to one embodiment, the step of applying the adhesion layer is implemented before the coupling step.

It is therefore clearly understood that the bonding layer is applied on the side of the manufacturing element facing the electronic device and that the adhesion layer is deposited on the other side of the manufacturing element, in particular facing the transfer support.

### BRIEF DESCRIPTION OF THE DRAWINGS

Other aspects, objects, advantages and characteristics of the invention will appear better on reading the following detailed description of preferred embodiments thereof, given by way of non-limiting example, and made with reference to the appended drawings on which:

FIG. 1 is a schematic view of the bonding phase of the manufacturing method according to a first particular embodiment of the invention.

FIG. 2 is a schematic view of the bonding phase of the manufacturing method according to a second particular embodiment of the invention.

FIG. 3 is a schematic view of the etching phase of the manufacturing method according to a particular embodiment of the invention.

FIG. 4 is a schematic view of the coupling step of the transfer phase according to a particular embodiment of the invention.

FIG. 5 is a schematic view of certain steps of the transfer phase of the manufacturing method according to a particular embodiment of the invention.

FIG. 6 is a schematic view of other steps of the transfer phase of FIG. 5.

FIG. 7 is a schematic view of the release phase and of the cleaning phase of the manufacturing method according to a particular embodiment of the invention.

FIG. 8 is a schematic view of the release phase and of the cleaning phase of the manufacturing method according to another particular embodiment of the invention.

### DETAILED DESCRIPTION

In the figures and in the remainder of the description, the same references represent identical or similar elements. In addition, the different elements are not represented to scale so as to favor the clarity of the figures. Moreover, the different embodiments and variants are not exclusive of each other and may be combined with each other.

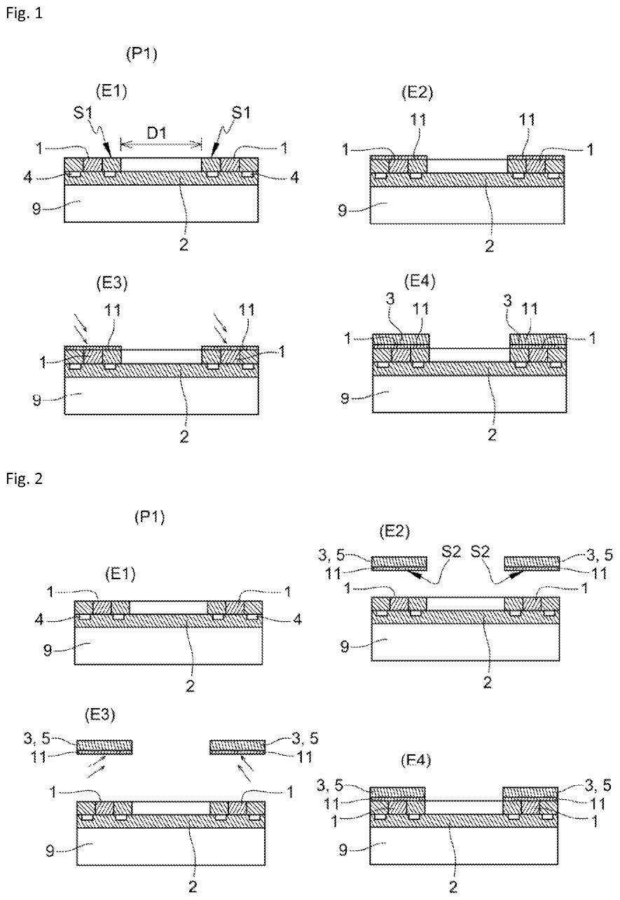

As illustrated in FIGS. 1 to 8, the invention concerns a method for manufacturing an electronic device 1, or a plurality of electronic devices 1 disposed on a primary substrate 9, being preferably intended to be fastened on a surface for receiving a secondary substrate 19, such as for example a substrate for a luminous display screen for the case of optoelectronic devices, which can be distributed over all or part of the free surface of the receiving surface.

The manufacturing method detailed below comprises a phase P1 of bonding said electronic device 1 to a manufacturing element 3, 7 and may also comprise an etching phase P2, a transfer phase P3, a release phase P4, and a cleaning phase P5.

With reference to FIGS. 1 and 2, the phase P1 of bonding the electronic device 1 relative to a manufacturing element 3, comprises a step E1 of providing a primary substrate 9 comprising at least one electronic device 1. For example, the primary substrate 9 may comprise a plurality of electronic devices 1 disposed on the surface of the primary substrate 9 at a first spacing D1. Advantageously, the plurality of electronic devices 1 may be attached to the primary substrate 9 via a primary adhesion layer 2. Each electronic device 1 may comprise an optoelectronic device comprising a light-emitting element comprising at least one light-emitting diode capable of emitting and/or capturing light, and possibly an electronic control component associated with said at least one light-emitting diode, such as for example a transistor. The electronic 1 or optoelectronic devices may have at least one interconnection pad 4 intended to cooperate with an interconnection interface 20 disposed on the surface of the secondary substrate 19. For example, each interconnection pad 4 may be intended to be welded to the interconnection interface 20.

According to a non-limiting variant, the electronic devices 1 may have dimensions comprised between 1 μm and 1 mm. Furthermore, the distance between the electronic devices 1 on the surface for receiving the secondary substrate 19 is comprised between 1 μm and 2 mm.

Each electronic device 1 has a surface, for example a surface to be protected S1 on which a bonding layer 11 consisting of a photosensitive polymer is applied so as to secure the bonding layer 11 and the electronic device 1 during a step E2. Alternatively or jointly, step E2 of applying a photosensitive polymer may be carried out on an interface surface S2 of the manufacturing element 3, 7. Said interface surface S2 is configured to be brought into contact with the electronic device 1 via the bonding layer 11, so as to secure the bonding layer 11 and the manufacturing element 3, 7. According to one embodiment, the manufacturing element 3 consists of a manufacturing substrate 5 on which a layer having the interface surface S2 is deposited. It is therefore well understood that the step E2 of applying a photosensitive polymer may be carried out on the surface to be protected S1 of the electronic device 1 as illustrated in FIG. 1, or on the interface surface S2 of the manufacturing element 3, as illustrated in FIG. 2, or jointly on the surface to be protected S1 and on the interface surface S2. Advantageously, the photosensitive polymer may be configured to react when subjected to a first luminous radiation having a first wavelength. For example, the photosensitive polymer may be configured to liquefy or to depolymerize when subjected to the first luminous radiation.

The bonding phase P1 may comprise a step E3 of treating the bonding layer 11 so as to increase the adherence of said bonding layer 11. For example, the treatment step E3 may comprise exposing the bonding layer 11 to a second luminous radiation having a second wavelength, different from the first wavelength. The second luminous radiation may in particular be configured to increase the surface adhesion of the bonding layer 11. In other words, the photosensitive polymer may be chosen so as to have an increase in its adhesive power when exposed to a second luminous radiation. For example, the photosensitive polymer may be a positive photoresist such as siloxane resins, polymetacrylates or polyformaldehydes, polyphenols or polyimides.

By photosensitive polymer is meant a polymer capable of undergoing a photoinduced chemical reaction for its polymerization or its depolymerization. For example, it may be a polymer/photo-initiator pair, such as a positive photoresist, or a polymer precursor and a given photo-initiator, such as a negative photoresist. Thus, the photosensitive polymer may comprise a photo initiator configured to polymerize the photosensitive polymer or to depolymerize it.

According to a non-limiting variant, the first luminous radiation is an ultraviolet radiation. Alternatively, the first luminous radiation may be an infrared or visible radiation.

For example, the first wavelength may be comprised between 190 nm and 390 nm and more particularly between 254 nm and 370 nm.

According to another non-limiting variant, the second luminous radiation is an ultraviolet radiation. Alternatively, the second luminous radiation may be an infrared or visible radiation.

For example, the second wavelength may be comprised between 400 nm and 2000 nm and more particularly between 400 nm and 800 nm.

In this case, and synergistically, the photosensitive polymer may absorb a large part of the first luminous radiation and may in this way absorb the radiation which may be harmful to the electronic device 1, in particular if the latter comprises an optoelectronic device.

According to one embodiment, the first luminous radiation and/or the second luminous radiation are emitted by coherent lasers. In this way, it is possible to select an irradiation area in which the first luminous radiation and/or the second luminous radiation are emitted. Said irradiation area may correspond to a surface covered by a photosensitive polymer, for example the bonding layer 11. Advantageously, the power of the coherent luminous radiation may thus be chosen sufficiently low so as not to damage the electronic device 1 and sufficiently strong to allow the adhesion of the photosensitive polymer to be modified.

The bonding phase P1 also comprises a step E4 of bringing the manufacturing element 3, 7 into contact with the electronic device 1 so as to adhere the manufacturing element 3, 7 to the electronic device 1 via the bonding layer 11. For example, step F4 of bringing the manufacturing element 3, 7 into contact with the electronic device 1 is implemented so as to adhere all or part of the interface surface S2 of the manufacturing element 3, 7 with all or part of the surface to be protected S1 of the electronic device 1 via the bonding layer 11. It is therefore well understood that, during step E4 of bringing the manufacturing element 3, 7 into contact with the electronic device 1, at least part of the interface surface S2 is in direct contact with at least part of a first face of the bonding layer 11, and that at least part of the surface to be protected S1 is in direct contact with at least part of a second face of the bonding layer 11 opposite to the first face. In this way, the bonding layer 11 is made up of a single element, and serves both to protect the electronic device 1, and to allow its adhesion with the manufacturing element 3, 7.

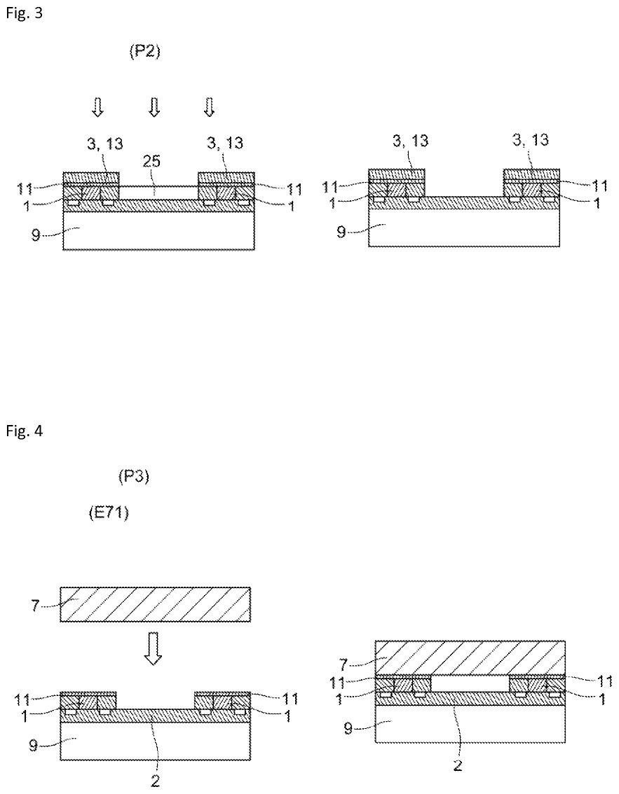

With reference to FIG. 3, it may be provided that the manufacturing element 3 comprises a protective mask 13, for example configured to protect the electronic devices 1 from etching. Advantageously, the protective mask 13 may be metallic, for example an aluminum mask, or a chrome mask or an aluminum nitride mask so as to carry out fine etching. Thus, the bonding layer 11 makes it possible both to bond the electronic devices 1 to the protective mask 13, and to protect said electronic devices 1 from possible damage caused by the protective mask 13. Alternatively, the protective mask 13 may consist of a non-metallic material such as SiO₂, or alternatively by a semiconductor layer.

In this case, the manufacturing method may comprise an etching phase P2 implemented after the bonding phase P1, in which an inter-device element 25 adjacent to the electronic device 1 undergoes an etching, for example a plasma etching, the protective mask 13 being configured to protect the electronic device 1 from said plasma etching. In general, the gas used for the plasma etching may be an octafluorocyclobutane/dioxygen mixture (C₄F₈/O₂), or carbon tetrafluoride (CF₄), or sulfur hexafluoride (SF₆).

As illustrated in FIGS. 4 to 6, the manufacturing method may comprise a phase P3 of transferring one or more electronic devices 1 from the primary substrate 9 to a secondary substrate 19 implemented after the bonding phase P1. The transfer phase P3 is notably implemented before the release phase P4.

According to a first embodiment, the manufacturing method may comprise a coupling step E71 during which a transfer support 7 is secured to each optoelectronic device 1 to be transferred via the bonding layer 11 as illustrated in FIG. 4. In this case, the transfer support 7 may constitute the manufacturing element 3.

In general, the coupling step E71 is implemented simply by the use of a transfer handle constituting the transfer support, which is capable of being secured to each electronic device 1, for example by adhesion with the bonding layer.

According to another variant, the coupling step E71 may be carried out by molding a molding material on each electronic device 1 so as to form the transfer support 7 by hardening the molding material. It is therefore well understood that the bonding layer 11 may be disposed between the transfer support 7 and the electronic device 1.

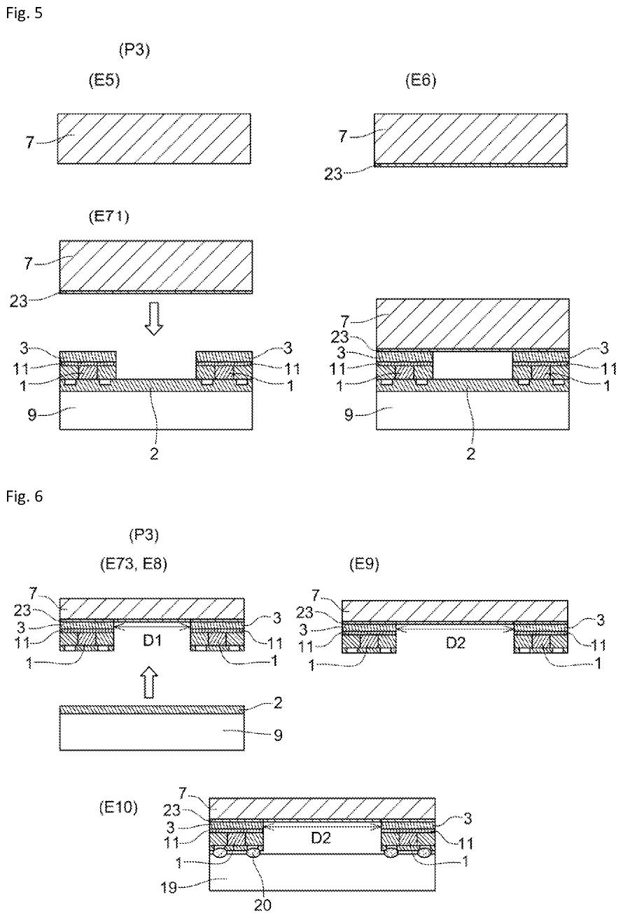

According to a second embodiment, distinct from the first embodiment and represented in FIGS. 5 and 6, the transfer support 7 is configured to cooperate with the manufacturing element 3. Step E71 of coupling the transfer support 7 to each electronic device 1 to be transferred is then implemented via the securing of the transfer support 7 with the manufacturing element 3. It is therefore well understood that according to this embodiment, the transfer support 7 is distinct from the manufacturing element 3. Thus, the transfer support 7 is indirectly secured to each electronic device 1 to be transferred via the manufacturing element 3 during the coupling step E71.

According to this embodiment, the transfer support 7 may comprise a transfer handle, made available during a step E5 of providing a transfer handle, and configured to cooperate with the manufacturing element 3, for example by gluing.

Alternatively, the transfer support 7 may be carried out by molding a molding material on the manufacturing element 3, so as to form the transfer support 7 by hardening the molding material.

Advantageously, the transfer support 17 may be made of a stretchable or shrinkable material.

The transfer phase P3 may further comprise a step E6 of applying an adhesion layer 23 to the transfer support 7, or to a surface of the manufacturing element 3 opposite to its surface intended to come into contact with the bonding layer 11. It is therefore well understood that the bonding layer 11 is applied on the side of the manufacturing element 3 facing the electronic device 1 and that the adhesion layer 23 is deposited on the other side of the manufacturing element 3, in particular facing the transfer support 7.

Advantageously, the adhesion layer 23 may be configured to have a sufficient adherence to allow the coupling of the transfer support 7 with the electronic device 1 via the manufacturing element 3, and the bonding layer 11 during coupling step E71. In particular, the adhesion layer 23 may be treated, for example by chemical treatment or by exposure to a luminous radiation.

The transfer phase P3 may then comprise a step E8 of unhooking said at least one electronic device 1 from the primary substrate 9 by mechanical traction or dry etching. The transfer support 7 may have gripping means configured to facilitate the movement of said transfer support 7.

In the case where the transfer support 7 is made of a stretchable or shrinkable material, it may then be stretched or compressed during a step E9 of stressing the transfer support 7. In this way, it is possible to stretch or to compress the transfer support 7 to vary a distance between two electronic devices 1, such as for example to reach a predetermined spacing. Advantageously, the predetermined spacing may be defined as the spacing separating two electronic devices 1 on the secondary substrate 19. For example the predetermined spacing may be comprised between 50 μm and 1 mm, and more particularly substantially equal to 100 μm. In this way, the transfer support 7 makes it possible to selectively transfer the electronic devices 1 to be deposited on the secondary substrate 19. Thus it is possible to unhook two electronic devices 1 on the primary substrate 9 according to a first spacing D1, and to place them on the secondary substrate 19 according to a second spacing D2 different from the first spacing. Advantageously, the second spacing D2 may be comprised between 1 μm and 2 mm.

Finally, the transfer phase P3 may comprise a step E10 of placing said at least one electronic device 1 on a surface for receiving a secondary substrate 19. In this way, the transfer support 7 makes it possible to simply transfer the electronic device 1 from the primary substrate 9 to the secondary substrate 19. The bonding layer 11 advantageously makes it possible to protect the electronic device 1 during said transfer from the primary substrate 9 to the secondary substrate 19. In particular, when the electronic device 1 is an optoelectronic device, the transfer support 7 makes it possible to simply transfer the optoelectronic device from the primary substrate 9 to a substrate for a luminous display screen. In general, a step E73 of moving the transfer support 7 may be implemented, during which the transfer support 7 is moved so as to implement the unhooking step E8 and/or the placing step E10.

As illustrated in FIG. 6, the step E10 of placing said at least one electronic device 1 on the surface for receiving the secondary substrate 19 may comprise the cooperation of each interconnection pad 4 with an interconnection interface 20 disposed on the surface of the secondary substrate 19, for example by welding. Advantageously, alignment elements, such as for example alignment marks associated with optical devices or lasers, may be provided to allow the placement of the electronic devices 1 on the surface for receiving the secondary substrate 19.

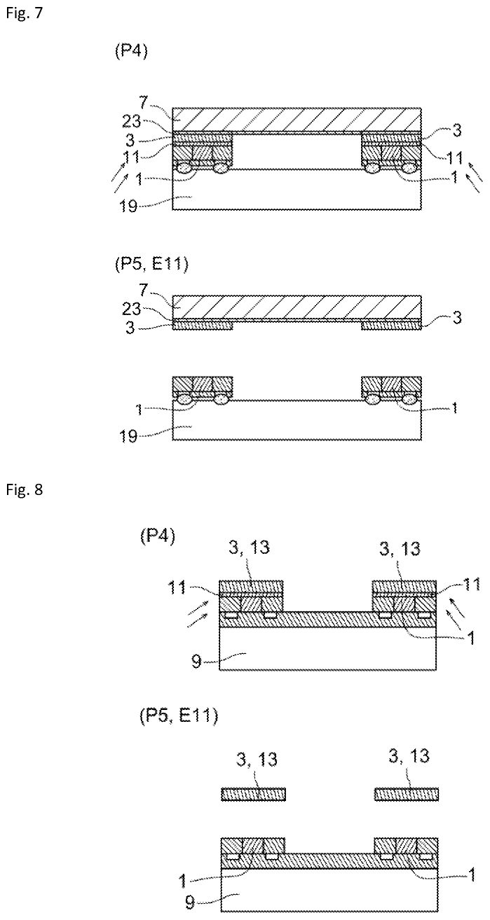

With reference to FIGS. 7 and 8, the manufacturing method further comprises a release phase P4 in which the bonding layer 11 is exposed to the first luminous radiation having a first wavelength so as to dissociate the manufacturing element 3 from the bonding layer 11. Thus, the release phase P4 makes it possible to separate the electronic device 1 from the manufacturing element 3, and consequently from the transfer support 7 when the latter is secured to the manufacturing element 3. A cleaning phase P5 which may be implemented after the release phase P4 comprises a step E11 of removing the photosensitive polymer by jet of plasma, solvent or air.

The arrangements previously described make it possible to propose a manufacturing method in which the electronic devices 1 are bonded to the manufacturing element 3, or to the transfer support 7 via the bonding layer 11. Furthermore, and synergistically, the bonding layer 11 also makes it possible to protect the electronic devices 1 against damage caused by contact with the manufacturing element 3, or the transfer support 7. In addition, the bonding layer 11 advantageously makes it possible to improve the adhesion of the electronic device 1 with the manufacturing element 3. The photosensitive properties of the polymer also make it possible to simply remove it during the release phase P4 without causing damage to 5 the surface of the electronic device 1.

In general, the dissociation of the manufacturing element 3 from the bonding layer 11 is carried out by liquefaction of the photosensitive polymer constituting the bonding layer 11 when it is subjected to the first luminous radiation.

The bonding layer 11 makes it possible to glue the electronic device 1 with the manufacturing element 3, and the release phase P4 makes it possible to unglue said manufacturing element 3 from the electronic device 1. In other words the protection P1 and release P4 phases allow reversible gluing and ungluing of the electronic device 1 and of the manufacturing element 3.

1. A method for manufacturing an electronic device (1) comprising a phase (P1) of bonding said electronic device (1) to a manufacturing element (3, 7), said bonding phase (P1) comprising:
a step (E1) of providing a primary substrate (9) comprising at least one electronic device (1);
a step (E2) of applying a bonding layer (11) consisting of a photosensitive polymer, during which the bonding layer (11) is applied to a surface of the electronic device (1) so as to secure the bonding layer (11) and the electronic device (1) and/or to an interface surface (S3) of the manufacturing element (3, 7) so as to secure the bonding layer (11) and the manufacturing element (3, 7);
a step (E4) of bringing the manufacturing element (3, 7) into contact with the electronic device (1) so as to adhere the manufacturing element (3, 7) to the electronic device (1) via the bonding layer (11);
the manufacturing method further comprising a release phase (P4) in which the bonding layer (11) is exposed to a first luminous radiation having a first wavelength so as to dissociate the manufacturing element (3, 7) from the electronic device (1).

2. The manufacturing method according to claim 1, wherein the bonding phase (P1) comprises a step (E3) of treating the bonding layer (11) so as to increase the adherence of said bonding layer (11), the treating step (E3) comprising exposing the bonding layer (11) to a second luminous radiation having a second wavelength, different from the first wavelength.

3. The manufacturing method according to claim 2, wherein the first luminous radiation and/or the second luminous radiation are emitted by coherent lasers.

4. The manufacturing method according to any one of claims 1 to 3, wherein the manufacturing element (3) comprises a protective mask (13), the manufacturing method comprising an etching phase (P2) implemented after the bonding phase (P1), in which an inter-device element (25) adjacent to the electronic device (1) undergoes etching, the protective mask (13) being configured to protect the electronic device (1) from said etching.

5. The manufacturing method according to claim 4, wherein the etching phase (P2) is carried out by a plasma etching.

6. The manufacturing method according to any one of claims 1 to 5, comprising a cleaning phase (P5) implemented after the release phase (P4), said cleaning phase (P5) comprising a step (E11) of removing the photosensitive polymer by jet of plasma, solvent or air.

7. The manufacturing method according to any one of claims 1 to 6, wherein the electronic device (1) comprises an optoelectronic device.

8. The manufacturing method according to any one of claims 1 to 7, wherein the first luminous radiation is an ultraviolet radiation.

9. The manufacturing method according to any one of claims 1 to 8, comprising a phase (P3) of transferring said at least one electronic device (1) from the primary substrate (9) to a secondary substrate (19) implemented after the bonding phase (P1), said transfer phase (P3) comprising:
a coupling step (E71) during which a transfer support (7) is secured to each electronic device (1) to be transferred;
a step (E8) of unhooking said at least one electronic device (1) from the primary substrate (9) by mechanical traction or dry etching;
a step (E10) of placing said at least electronic device (1) on a surface for receiving the secondary substrate (19).

10. The manufacturing method according to claim 9, wherein the transfer phase (P3) is implemented before the release phase (P4).

11. The manufacturing method according to any one of claim 9 or 10, wherein the transfer phase (P3) further comprises a step (E73) of moving the transfer support (7) during which the transfer support (7) is moved so as to implement the unhooking step (E8) and/or the positioning step (E10).

12. The manufacturing method according to any one of claims 9 to 11, wherein the manufacturing element (3) consists of the transfer support (7).

13. The manufacturing method according to any one of claims 9 to 11, wherein the transfer support (7) is configured to cooperate with the manufacturing element (3), the step (E71) of coupling the transfer support (7) to each electronic device (1) to be transferred being implemented via the securing of the transfer support (7) with the manufacturing element (3).

14. The manufacturing method according to claim 13, wherein the transfer support (7) is made of a stretchable or shrinkable material.

15. The manufacturing method according to claim 14, wherein the transfer phase (P3) comprises a step (E9) of stressing the transfer support (7) in which the transfer support (7) is stretched or compressed.

16. The manufacturing method according to any one of claims 13 to 15, wherein the transfer phase (P3) comprises a step (E6) of applying an adhesion layer (23) to the transfer support (7), or to a surface of the manufacturing element (3) opposite to its surface intended to come into contact with the bonding layer (11).

17. The manufacturing method according to claim 16, wherein the step (E6) of applying an adhesion layer (23) is implemented before the coupling step (E71).
